(19) United States
(12) Patent Application Publication
(10) Pub. No.: US 2024/0251569 A1
(43) Pub. Date: Jul. 25, 2024

(54) SEMICONDUCTOR DEVICE AND METHOD FOR FABRICATING THE SAME

(71) Applicant: SK hynix Inc., Icheon (KR)

(72) Inventors: Chi Ho KIM, Icheon (KR); Kyung Seop KIM, Icheon (KR); Hun KIM, Icheon (KR); Young Cheol SONG, Icheon (KR); Chang Jun YOO, Icheon (KR); Jae Wan CHOI, Icheon (KR)

(21) Appl. No.: 18/346,634

(22) Filed: Jul. 3, 2023

(30) Foreign Application Priority Data
Jan. 20, 2023 (KR) 10-2023-0008829

(51) Int. Cl. H10B 63/00; H10B 63/10

(52) U.S. Cl. CPC H10B 63/80; H10B 63/10; H10B 63/20

(57) ABSTRACT

A semiconductor device includes: a substrate; a plurality of memory cells positioned over the substrate, each of the plurality of memory cells having a multi-layer structure including a memory pattern; a sealing layer pattern filling a lower portion of a space between the memory cells, the lower portion being positioned below a bottom surface of the memory pattern; a liner layer pattern formed along a surface of an upper portion of the space to partially fill the upper portion; and a dielectric layer pattern filling a remaining portion of the space unfilled by the sealing layer pattern and the liner layer pattern.

### CROSS-REFERENCE TO RELATED APPLICATIONS

The present application claims priority of Korean Patent Application No. 10-2023-0008829, filed on Jan. 20, 2023, which is incorporated herein by reference in its entirety.

### BACKGROUND

### 1. Field

Embodiments of the present disclosure relate to a semiconductor technology, and more particularly, to a semiconductor device provided with memory cells including a memory pattern that generates heat during an operation, such as a phase-change pattern, and a method for fabricating the same.

### 2. Description of the Related Art

To satisfy the recent demands for the miniaturization, low power consumption, high-performance, and diversification of electronic devices, researchers and the industry study and develop semiconductor devices that can store data and information in diverse electronic devices, such as computers and portable communication devices. Among them are the semiconductor devices that can store data based on the characteristics of switching between different resistance states according to a voltage or current applied to the semiconductor devices, for example, a Resistive Random Access Memory (RRAM), a Phase-Change Random Access Memory (PRAM), a Ferroelectric Random Access Memory (FRAM), a Magnetic Random Access Memory (MRAM), an E-fuse and the like.

### SUMMARY

Embodiments of the present disclosure are directed to a semiconductor device that may improve the operation characteristics of memory cells and reduce the process difficulty, and a method for fabricating the semiconductor device.

In accordance with an embodiment of the present disclosure, a semiconductor device includes: a substrate; a plurality of memory cells positioned over the substrate, each of the plurality of memory cells having a multi-layer structure including a memory pattern; a sealing layer pattern filling a lower portion of a space between the memory cells, the lower portion being positioned below a bottom surface of the memory pattern; a liner layer pattern formed along a surface of an upper portion of the space to partially fill the upper portion; and a dielectric layer pattern filling a remaining portion of the space unfilled by the sealing layer pattern and the liner layer pattern.

In accordance with another embodiment of the present disclosure, a method for fabricating a semiconductor device includes: forming a plurality of memory cells, each of the plurality of memory cells having a multi-layer structure including a memory pattern over a substrate; forming a sealing layer of a thickness that fills a space between the memory cells; forming a sealing layer pattern by removing a portion of the sealing layer to expose a sidewall of the memory pattern; forming a liner layer along a portion of a sidewall of the memory cell exposed by the sealing layer pattern and an upper surface of the sealing layer pattern; and forming a dielectric layer over the liner layer.

In accordance with another embodiment of the present disclosure, a method for fabricating a semiconductor device includes: forming stacked structures, each of the stacked structures including a lower conductive line and an initial memory cell, the initial memory cell having a multi-layer structure including an initial memory pattern, the initial memory cell extending in a first direction over a substrate; forming a first sealing layer filling a space between the stacked structures; forming a first sealing layer pattern by removing a portion of the first sealing layer to expose a sidewall of the initial memory pattern; forming a first liner layer over a portion of a sidewall of the initial memory cell exposed by the first sealing layer pattern and an upper surface of the first sealing layer pattern; forming a first dielectric layer over the first liner layer; forming a first liner layer pattern and a first dielectric layer pattern by performing a planarization process to expose an upper surface of the initial memory cell; forming a plurality of upper conductive lines extending in a second direction crossing the first direction over the initial memory cell, the first liner layer pattern, and the first dielectric layer pattern; and forming a plurality of memory cells by etching the initial memory cell exposed by the upper conductive lines, each of the plurality of memory cells including a memory pattern.

### BRIEF DESCRIPTION OF THE DRAWINGS

FIGS. 1A and 1B illustrate a semiconductor device in accordance with an embodiment of the present disclosure.

FIGS. 2, 3, 4, 5, and 6 illustrate a semiconductor device and a method for fabricating the same in accordance with another embodiment of the present disclosure.

FIGS. 7, 8, 9, 10, 11, 12, 13, 14, 15, and 16 illustrate a semiconductor device and a method for fabricating the same in accordance with another embodiment of the present disclosure.

### DETAILED DESCRIPTION

Exemplary embodiments of the present disclosure will be described below in more detail with reference to the accompanying drawings. The present disclosure may however, be embodied in different forms and should not be construed as limited to the embodiments set forth herein. Rather, these embodiments are provided so that this disclosure will be thorough and complete, and will fully convey the scope of the present disclosure to those skilled in the art. Throughout the disclosure, like reference numerals refer to like parts throughout the diverse figures and embodiments of the present disclosure.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

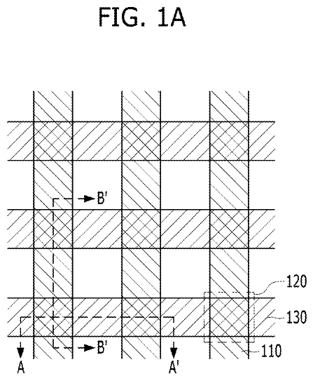

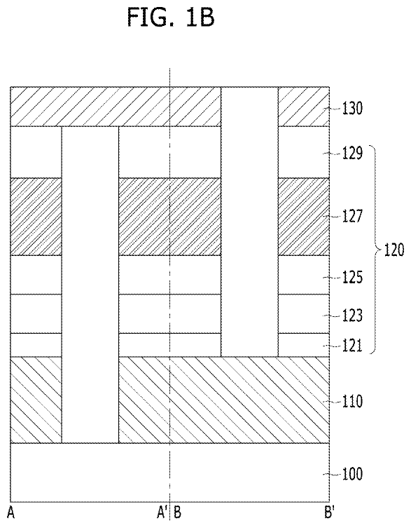

FIGS. 1A and 1B illustrate a semiconductor device in accordance with an embodiment of the present disclosure. FIG. 1A is a plan view, and FIG. 1B shows cross-sectional views taken along a line A-A′ and a line B-B′ shown in FIG. 1A.

Referring to FIGS. 1A and 1B, the semiconductor device in accordance with the embodiment of the present disclosure may include a substrate 100, a lower conductive line 110 formed over the substrate 100 and extending in parallel to the line B-B′, an upper conductive line 130 formed to be spaced apart from the lower conductive line 110 in parallel to the line A-A′ over the lower conductive line 110, and memory cells 120 each positioned between the lower conductive line 110 and the upper conductive line 130 at the intersection between the lower conductive line 110 and the upper conductive line 130. For the sake of convenience in description, the direction that the lower conductive line 110 extends will be referred to as a first direction, and the direction that the upper conductive line 130 extends will be referred to as a second direction. The first and second directions may cross each other, that is, may be substantially orthogonal to each other, while being substantially parallel to the surface of the substrate 100.

The substrate 100 may include a semiconductor material, such as silicon. In the substrate 100, a required predetermined lower structure (not shown) may be formed. For example, the substrate 100 may include a driving circuit (not shown) that is electrically connected to the lower conductive line 110 and/or the upper conductive line 130 to control the lower conductive line 110 and/or the upper conductive line 130.

Each of the lower conductive line 110 and the upper conductive line 130 may include diverse conductive materials, such as metals, e.g., platinum (Pt), tungsten (W), aluminum (Al), copper (Cu), tantalum (Ta) and the like, metal nitrides, e.g., titanium nitride (TiN), tantalum nitride (TaN) and the like, or combinations thereof, and have a single layer structure or a multi-layer structure. The lower conductive line 110 and the upper conductive line 130 may be connected to the lower and upper ends of the memory cells 120, respectively, to drive the memory cells 120 by applying a voltage or current to the memory cells 120. When the lower conductive line 110 functions as a word line, the upper conductive line 130 may function as a bit line. On the contrary, when the lower conductive line 110 functions as a bit line, the upper conductive line 130 may function as a word line.

The memory cells 120 may be a device for storing different data depending on the voltage or current applied to the lower conductive line 110 and the upper conductive line 130. The memory cells 120 may have a pillar shape. For example, from the perspective of a plane, the memory cells 120 may have both sidewalls in the first direction to be aligned with both sidewalls of the upper conductive line 130, and both sidewalls in the second direction to be aligned with both sidewalls of the lower conductive line 110. It may have a square shape. However, the concept and spirit of the present disclosure are not limited thereto, and the planar shape may vary as long as each of the memory cells 120 overlaps with the intersection between the lower conductive line 110 and the upper conductive line 130. Also, the alignment between the memory cells 120 and the sidewalls of the lower conductive line 110 and/or the upper conductive line 130 may not be essential.

The memory cells 120 may include at least a phase-change pattern 127 in order to store different data. The phase-change pattern 127 may switch between an amorphous state and a crystalline state by the joule's heat which is generated based on the current flowing through the phase-change pattern 127. When the phase-change pattern 127 is in an amorphous state, the phase-change pattern 127 may be in a relatively high resistance state. On the other hand, when the phase-change pattern 127 is in a crystalline state, the phase-change pattern 127 may be in a relatively low resistance state. Data may be stored using the difference in the resistance of the phase-change pattern 127.

Also, the memory cells 120 may have a multi-layer structure including the phase-change pattern 127. For example, the memory cells 120 may include a stacked structure of the bottom electrode 121, a selector pattern 123, an intermediate electrode 125, the phase-change pattern 127, and the top electrode 129.

The bottom electrode 121 may be positioned at the bottom of the memory cells 120 to provide a connection with the lower conductive line 110. The intermediate electrode 125 may be interposed between the phase-change pattern 127 and the selector pattern 123 to electrically connect the phase-change pattern 127 and the selector pattern 123 to each other while physically separating them from each other. The top electrode 129 may be positioned at the top of the memory cells 120 to provide a connection with the upper conductive line 130. Each of the bottom electrode 121, the intermediate electrode 125, and the top electrode 129 may include one or more conductive materials, such as metals, e.g., platinum (Pt), tungsten (W), aluminum (Al), copper (Cu), tantalum (Ta) and the like, metal nitrides, e.g., titanium nitride (TiN), tantalum nitride (TaN) and the like, or combinations thereof, or may include a carbon electrode.

The selector pattern 123 may have a threshold switching characteristics of blocking the current or holding the current when the level of the voltage supplied to the top and bottom portions of the selector pattern 123 is lower than a predetermined threshold voltage, and then when the voltage level becomes equal to or greater than the threshold voltage, letting the current flow abruptly. With the threshold switching characteristics, it may control the access to the phase-change pattern 127. The selector pattern 123 may include an Ovonic Threshold Switching (OTS) material, such as a diode and chalcogenide-based materials, a Mixed Ionic Electronic Conducting (MIEC) material, such as a metal-containing chalcogenide-based material and the like, a Metal Insulator Transition (MIT) material, such as NbO₂ and VO₂, or a tunneling dielectric material having a relatively wide band gap, such as SiO₂, Al₂O₃, and the like. Also, the selector pattern 123 may include a dielectric material doped with a dopant. Here, the dielectric material may include silicon-containing dielectric materials, such as silicon oxide, silicon nitride, silicon oxynitride and the like, dielectric metal oxides, dielectric metal nitrides, and combinations thereof. The dopant may serve to form a trap site for capturing a conductive carrier moving in a dielectric material or providing a passage through which the captured conductive carrier may move again. In order to form the trap site, diverse elements capable of generating energy potential that may accommodate the conductive carriers in a dielectric material may be used as the dopant. For example, when a dielectric material contains silicon, the dopant may include a metal whose valence is different from that of silicon, such as gallium (Ga), boron (B), indium (in), phosphorus (P), arsenic (AS), and antimony (Sb), germanium (Ge), carbon (C), tungsten (W), or a combination thereof. Also, when the dielectric material contains a metal, the dopant may include another metal whose valence is different from that of the metal contained in the dielectric material, silicon, and the like. For example, the selector pattern 123 may include a silicon oxide (SiO₂) that is doped with arsenic (As). When a voltage equal to or greater than the threshold voltage is applied to the selector pattern 123 including a dielectric material that is doped with the dopant, the conductive carrier may move through the trap site, thereby realizing an on-state in which current flows through the selector pattern 123. When the voltage applied to the selector pattern 123 is reduced to a level lower than the threshold voltage, an off-state in which no conductive carrier moves and the current does not flow may be realized.

While the memory cells 120 may include the phase-change pattern 127, the multi-layer structure of the memory cells 120 may vary according to embodiments. For example, one or more of the bottom electrode 121, the selector pattern 123, the intermediate electrode 125, and the top electrode 129 may be omitted. Also, for example, the memory cells 120 may further include one or more layers (not shown) for improving a process or characteristics.

The semiconductor device described above may require the following.

First of all, in order to support and protect the memory cells 120, it is desirable to substantially completely fill the space between the memory cells 120 with a dielectric material. However, as the memory cells 120 have a multi-layer structure, the height of the memory cells 120 are increased, and the width of the memory cells 120 and the width of the space between the memory cells 120 may be decreased as the integration of the semiconductor device increases. In other words, the aspect ratio of the space between the memory cells 120 is increasing. This increases the difficulty of the process of filling the space between the memory cells 120 with a dielectric material.

Also, it is desirable to prevent and/or reduce the heat generated to change the state of the phase-change pattern 127 of the memory cells 120 from being lost or delivered to the surrounding region. If the heat is lost or delivered to the phase-change pattern 127 of another neighboring memory cell 120, there may be a problem of requiring a greater operation current to the change the state of the phase-change pattern 127, or a problem of thermal disturbance of affecting the neighboring phase-change pattern 127, which may deteriorate the operation characteristics of the memory cells 120. Therefore, it may be desirable to fill the space between the neighboring phase-change patterns 127 with a dielectric material having a low thermal conductivity.

Also, since the phase-change pattern 127 of the memory cells 120 and the other portion of the memory cells 120 except the phase-change pattern 127 have different materials and characteristics, it may be desirable to optimize the characteristics or fabrication method of the memory cells 120 and the semiconductor device including the memory cells 120 by controlling a dielectric material between the phase-change patterns 127 and a dielectric material between other portions of the memory cells 120 than the phase-change patterns 127. For example, whereas the space between the phase-change patterns 127 includes a dielectric material having a low thermal conductivity as described above, the space between the portions positioned below the phase-change pattern 127 of the memory cells 120 may require a dielectric material with excellent filling characteristics rather than a dielectric material with a low thermal conductivity. This is because, as described above, a material with excellent filling characteristics is required to completely fill the space with a high aspect ratio, such as the space between the memory cells 120, from bottom to top.

Hereafter, a semiconductor device and a method for fabricating the semiconductor device that may address these issues will be described.

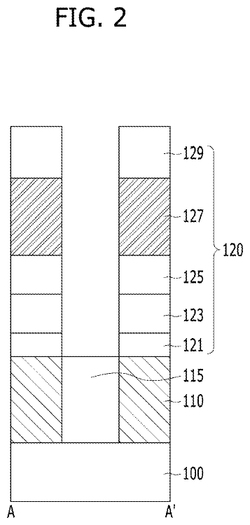

FIGS. 2 to 6 illustrate a semiconductor device and a method for fabricating the same in accordance with an embodiment of the present disclosure. FIGS. 2 to 6 are illustrated according to the cross-sectional direction taken along the line A-A′ of FIG. 1A. The same reference numbers may be given to the same constituent elements that are substantially the same as what is illustrated in FIGS. 1A and 1B, and the detailed description thereon may be omitted for the interest of brevity.

First, the fabrication method will be described.

Referring to FIG. 2, lower conductive lines 110 and an inter-layer dielectric layer 115 filling the space between the lower conductive lines 110 may be formed over a substrate 100.

The lower conductive lines 110 may be arranged to be spaced apart from each other in the second direction while extending in the first direction. The inter-layer dielectric layer 115 may include silicon oxide, silicon nitride, silicon oxynitride, or a combination thereof.

The lower conductive line 110 and the inter-layer dielectric layer 115 may be formed by depositing a conductive material for forming the lower conductive line 110 over the substrate 100, selectively etching the conductive material to form the lower conductive line 110, depositing a dielectric material in a thickness that sufficiently fill the space between the lower conductive lines 110 over the substrate 100 and the lower conductive lines 110, and performing a planarization process, such as a Chemical Mechanical Polishing (CMP) process, until the upper surface of the lower conductive lines 110 is exposed.

Subsequently, column-shaped memory cells 120 may be formed over the lower conductive lines 110 and the inter-layer dielectric layer 115. Accordingly, although not shown, the shape and arrangement of the memory cells 120 in the cross-section taken along the line B-B′ of FIG. 1A may be substantially the same as what is illustrated in FIG. 2.

The memory cells 120 may be formed by sequentially depositing material layers for forming the memory cells 120 over the lower conductive lines 110 and the inter-layer dielectric layer 115, such as a bottom electrode layer, a selector layer, an intermediate electrode layer, a phase-change material layer, and a top electrode layer, and selectively etching them. The memory cells 120 may include a stacked structure of a bottom electrode 121, a selector pattern 123, an intermediate electrode 125, a phase-change pattern 127, and a top electrode 129. In this case, the sidewalls of the memory cells 120 may not be necessarily aligned with the sidewalls of the lower conductive line 110 and the sidewall of an upper conductive line 130, as will be described later. This is because the mask pattern for forming the lower conductive line 110 and the mask pattern for forming of the memory cells 120 may be different.

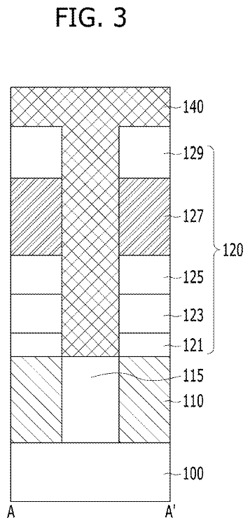

Referring to FIG. 3, a sealing layer 140 that fills the space between the memory cells 120 over the resultant structure of the process of FIG. 2 may be formed.

The sealing layer 140 may be formed of a material with desirable gap-fill characteristics so that the space between the memory cells 120 may be substantially completely filled. For example, the sealing layer 140 may include at least one selected among dielectric silicon-containing materials, such as SiN, SiON, SiCN, SiOC, SiOCN, SiC, SiO, and the like, and dielectric metal oxides, such as hafnium oxide, lanthanum oxide and the like. Furthermore, for example, the sealing layer 140 may include nitrides, such as SiN to prevent oxidation of the selector pattern 123.

Also, the sealing layer 140 may be formed at a relatively low temperature, e.g., at a temperature of lower than approximately 400° C. This is because the selector pattern 123 may be damaged when it is exposed at a high process temperature according to its type. For example, when the selector pattern 123 includes an OTS material, it may be damaged when it is exposed to a temperature of approximately 400° C. or higher. Therefore, the process for forming the sealing layer 140 may be performed at a relatively low temperature to substantially prevent the selector pattern 123 from being damaged.

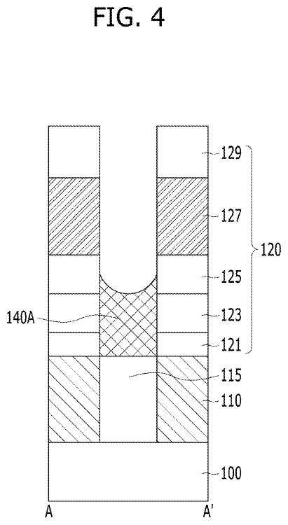

Referring to FIG. 4, a sealing layer pattern 140A may be formed by removing a portion of the sealing layer 140 in such a manner that the entire sidewall of the phase-change pattern 127 is exposed. The partial removal of the sealing layer 140 may be performed by a recess process using dry etching and wet etching.

As a result of this process, the upper surface of the sealing layer pattern 140A may be positioned at a height substantially equal to or lower than the lower surface of the phase-change pattern 127 and cover the sidewall of the memory cells 120 that are positioned at a height equal to or lower than the lower surface of the phase-change pattern 127. For example, the sealing layer pattern 140A may cover the selector pattern 123 while directly contacting the sidewall of the selector pattern 123. Also, during the recess process for the sealing layer 140, the etching rate in a region relatively adjacent to the memory cells 120 may be lower than the etching rate in a region relatively far from the memory cells 120. Accordingly, the height of the upper surface of the sealing layer pattern 140A at a point that is relatively adjacent to the memory cells 120 may be higher than the height at a point that is relatively far from the memory cells 120. In other words, as illustrated in FIG. 4, the upper surface of the sealing layer pattern 140A may have a sunken shape whose height is high in the edges and low in the center.

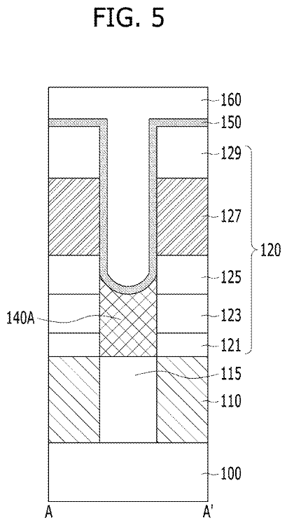

Referring to FIG. 5, a liner layer 150 and a dielectric layer 160 may be formed over the resultant structure of the process of FIG. 4.

The liner layer 150 may be formed to protect the phase-change pattern 127 during the subsequent process for forming the dielectric layer 160, and the liner layer 150 may be formed conformally along the profile of the resultant structure of the process of FIG. 4. In other words, the liner layer 150 may be formed to directly contact portions of the resultant structure of FIG. 4 that are not covered by the sealing layer pattern 140A, particularly the sidewall of the phase-change pattern 127, the upper surface of the memory cells 120, and the upper surface of the sealing layer pattern 140A. To this end, the liner layer 150 may be formed of a material with desirable step coverage characteristics. For example, the liner layer 150 may include at least one selected among dielectric silicon-containing materials, such as SiN, SiON, SiCN, SiOC, SiOCN, SiC, SiO and the like, and dielectric metal oxides, such as hafnium oxide, lanthanum oxide and the like.

The liner layer 150 may be formed of a material which is the same as or different from that of the sealing layer 140. For example, the sealing layer 140 may include SiN, and the liner layer 150 may include SiCN.

Also, the liner layer 150 may be formed at a relatively high temperature, e.g., at a temperature of higher than approximately 400° C. In other words, the temperature of the process for forming the liner layer 150 may be higher than the temperature of the process for forming the sealing layer 140. Since the selector pattern 123 is protected by the sealing layer pattern 140A, even though the high temperature process is performed, the selector pattern 123 may be protected from being damaged. Since the phase-change pattern 127 is less sensitive to temperature compared to the selector pattern 123, there may be no issue even though the phase-change pattern 127 is exposed to a relatively high temperature process. As described, when the liner layer 150 is formed through the high temperature process, the film quality of the liner layer 150 may be improved, further improving the function of protecting the phase-change pattern 127 by the liner layer 150.

Meanwhile, in a comparative example in which the processes for forming the sealing layer and the sealing layer pattern are omitted, the liner layer may be formed along the entire sidewall of the memory cell. In this case, since the liner layer should have excellent step coverage characteristics, there may be constraints on the material for forming the liner layer and/or the process for forming the liner layer. On the other hand, according to the embodiment of the present disclosure, the sealing layer pattern 140A may be formed first in the space between the memory cells 120, which may decrease the aspect ratio of the space in which the liner layer 150 is formed, compared to that of the comparative example. Therefore, there may be no issue even though the step coverage characteristics of the liner layer 150 is reduced compared to that of the liner layer according to the comparative example. In short, the embodiment of the present disclosure has beneficial aspects of relieving the constraints on the material for forming the liner layer 150 and/or the process for forming the liner layer 150. Also, when the aspect ratio of the space in which the liner layer 150 is formed is reduced, the thickness of the liner layer 150 may be increased compared to the comparative example. Therefore, the function of protecting the phase-change pattern 127 may be further improved.

The dielectric layer 160 may be formed in a thickness that may sufficiently fill the space between the memory cells 120 where the sealing layer pattern 140A and the liner layer 150 are formed. The dielectric layer 160 may be formed to prevent and/or reduce the loss of heat from the phase-change pattern 127 or transfer of the heat between the phase-change pattern 127, and the dielectric layer 160 may include a dielectric material having a low thermal conductivity. The thermal conductivity of the dielectric layer 160 may be lower than the thermal conductivity of the sealing layer pattern 140A and the thermal conductivity of the liner layer 150. For example, the dielectric layer 160 may include a material with a thermal conductivity value of less than approximately 0.04 W/mK. For example, the dielectric layer 160 may include at least one selected among dielectric silicon-containing materials, such as SiN, SiON, SiCN, SiOC, SiOCN, SiC, SiO, and the like, and dielectric metal oxides, such as hafnium oxide, lanthanum oxide and the like. The dielectric layer 160 may be formed of a material that is different from those of the sealing layer 140 and the liner layer 150. For example, when the sealing layer 140 includes SiN and the liner layer 150 includes SiCN, the dielectric layer 160 may include SiOC.

Meanwhile, according to the comparative example where the processes for forming the sealing layer and the sealing layer pattern are omitted, the dielectric layer needs to fill the whole space between the memory cells where the liner layer is formed. In this case, since the dielectric layer should have excellent gap-fill characteristics, there may be constraints on the material for forming the dielectric layer and/or the process for forming the dielectric layer. On the other hand, according to the embodiment of the present disclosure, the sealing layer pattern 140A may be formed first in the space between the memory cells 120, which may decrease the aspect ratio of the space in which the dielectric layer 160 is formed, compared to that of the comparative example. Therefore, there may be no problem even though the gap-fill characteristics of the dielectric layer 160 is reduced compared to that of the dielectric layer according to the comparative example. In short, the embodiment of the present disclosure has beneficial aspects of relieving the constraints on the material for forming the dielectric layer 160 and/or the process for forming the dielectric layer 160.

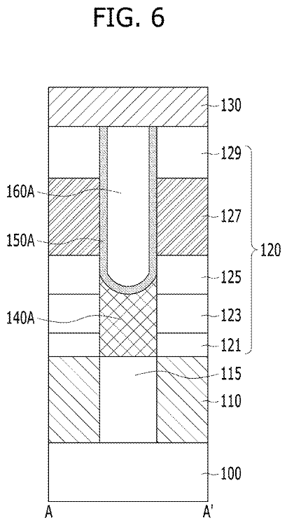

Referring to FIG. 6, a liner layer pattern 150A and a dielectric layer pattern 160A may be formed by performing a planarization process until the upper surface of the memory cells 120 is exposed in order to remove the liner layer 150 and the dielectric layer 160 from the upper surface of the memory cells 120. As described above, since the film quality of the liner layer pattern 150A is improved and enhanced, the liner layer pattern 150A may function as a stopping layer for the planarization process during the planarization process, thereby securing process margins.

Subsequently, an upper conductive line 130 may be formed over the memory cells 120, the liner layer pattern 150A, and the dielectric layer pattern 160A.

The upper conductive lines 130 may be arranged to be spaced apart from each other in the first direction while extending in the second direction. The upper conductive lines 130 may be formed by depositing a conductive material for forming the upper conductive lines 130 over the memory cells 120, the liner layer pattern 150A, and the dielectric layer pattern 160A, and selectively etching the conductive material. Although not illustrated in this cross-sectional view, the space between the upper conductive lines 130 may be filled with another inter-layer dielectric layer.

A semiconductor device according to an embodiment of the present disclosure may be obtained by the fabrication method described above.

Referring again to FIG. 6, the semiconductor device in accordance with the embodiment of the present disclosure may include a substrate 100, a lower conductive line 110 formed over the substrate 100 and extending in the first direction, an upper conductive line 130 formed to be spaced apart from the lower conductive line 110 over the lower conductive line 110 and extending in the second direction crossing the first direction, column-shaped memory cells 120 each positioned at the intersection between the lower conductive line 110 and the upper conductive line 130, and a sealing layer pattern 140A, a liner layer pattern 150A, and a dielectric layer pattern 160A filling the space between the memory cells 120.

The memory cells 120 each may have a multi-layer structure including a memory pattern that functions as a data storage element. In an embodiment, the memory pattern may be a phase-change pattern 127. For example, the memory cells 120 in FIG. 6 may have a stacked structure of a bottom electrode 121, a selector pattern 123, an intermediate electrode 125, a phase-change pattern 127, and a top electrode 129.

Here, the sealing layer pattern 140A may fill at least a first portion of the space between the memory cells 120 neighboring in the second direction. For example, the first portion of the space may be a lower portion positioned below the bottom surface of the phase-change pattern 127. In other words, the upper surface of the sealing layer pattern 140A may be positioned at a height substantially equal to or lower than the bottom surface of the phase-change pattern 127. Furthermore, the upper surface of the sealing layer pattern 140A may have a sunken shape whose height is high at the edges and low in the center. For example, a height of the upper surface of the sealing layer pattern 140A may decrease from the edge to the center of the upper surface of the sealing layer pattern 140A. Accordingly, the height at a first point of the upper surface of the sealing layer pattern 140A at a first distance from the memory cell 120 in the horizontal direction may be higher than the height at a second point of the upper surface of the sealing layer pattern 140A at a second distance in the horizontal direction from the memory cell 120, where the second distance is greater than the first distance. For example, the height at the first point contacting the memory cells 120 on the upper surface of the sealing layer pattern 140, that is, the height of an edge, may be higher than the height at the second point which is positioned at the same distance from two neighboring memory cells 120 on the upper surface of the sealing layer pattern 140A, that is, the height of the center.

The liner layer pattern 150A may be formed on the upper surface of the sealing layer pattern 140A, and the sidewalls of the memory cells 120 which are not covered by the sealing layer pattern 140A, and may be conformally formed in a thin thickness that does not completely fill the space between the memory cells 120 where the sealing layer pattern 140A is formed. For example, the liner layer pattern 150A may be formed along a surface of a second portion (e.g., an upper portion) of the space between the memory cells 120 neighboring in the second direction, where the upper portion of the space is positioned over the lower portion of the space. Since the sealing layer pattern 140A fills the lower portion of the space and the linear layer pattern 150A may have a relatively thin thickness to partially fill the upper portion of the space, a portion of the space remains unfilled by the sealing layer pattern 140A and the liner layer pattern 150A.

The dielectric layer pattern 160A may be formed to fill the space between the memory cells 120 where the sealing layer pattern 140A and the liner layer pattern 150A are formed. In other words, the dielectric layer 160A may fill the remaining portion of the space unfilled by the sealing layer pattern 140A and the liner layer pattern 150A.

Each of the sealing layer pattern 140A, the liner layer pattern 150A, and the dielectric layer pattern 160A, may include at least one selected among dielectric silicon-containing materials, such as SiN, SiON, SiCN, SiOC, SiOCN, SiC, SiO and the like, and dielectric metal oxides, such as hafnium oxide, lanthanum oxide and the like. For example, each of the sealing layer pattern 140A, the liner layer pattern 150A, and the dielectric layer pattern 160A, may include at least one dielectric silicon-containing material, or at least one dielectric metal oxide, or at least one dielectric silicon-containing material and at least one dielectric metal oxide. The sealing layer pattern 140A and the liner layer pattern 150A may include the same material or different materials. On the other hand, the dielectric layer pattern 160A may be formed of a material that is different from those of the sealing layer pattern 140A and the liner layer pattern 150A, and may include a material having a lower thermal conductivity than the sealing layer pattern 140A and the liner layer pattern 150A. For example, the sealing layer pattern 140A may include SiN, and the liner layer pattern 150A may include SiCN, and the dielectric layer pattern 160A may include SiOC.

According to the semiconductor device and the fabrication method thereof which are described above, the difficulty of the filling process may be reduced even though the aspect ratio of the space between the memory cells 120 is large. Also, the operation characteristics of the semiconductor device may be improved by forming a dielectric material that may optimize the characteristics between the phase-change patterns 127 and between the selector patterns 123 through a separate process.

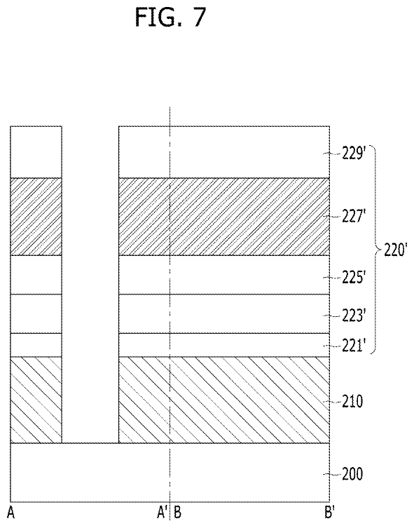

Meanwhile, according to the above embodiment of the present disclosure, the process of patterning the lower conductive line 110, the memory cells 120, and the upper conductive line 130 by using separate masks, but the concept and spirit of the present disclosure are not limited thereto. According to another embodiment of the present disclosure, the memory cells may be patterned using a mask for forming the lower conductive line and a mask for forming the upper conductive line. In this case, the process for forming the sealing layer pattern, the process for forming the liner layer pattern, and the process for forming the dielectric layer pattern, which are described above, may be performed twice. Hereinafter, this will be exemplarily described by referring to FIGS. 7 to 16.

FIGS. 7 to 16 illustrate a semiconductor device and a method for fabricating the same in accordance with another embodiment of the present disclosure. FIGS. 7 to 16 are cross-sectional views taken along a line A-A′ and a line B-B′ shown in FIG. 1A. Detailed description on the constituent elements also appearing in FIGS. 1A and 1B may be omitted for the interest of brevity.

First, the fabrication method will be described.

Referring to FIG. 7, a lower conductive line 210 over a substrate 200 and an initial memory cell 220′ that overlaps with the lower conductive line 120 over the lower conductive line 210 may be formed.

The stacked structure of the lower conductive line 210 and the initial memory cells 220′ may be arranged to be spaced apart from each other in the second direction while extending in the first direction. The lower conductive line 210 and the initial memory cell 220′ may be formed by depositing a conductive material for forming the lower conductive line 210 over the substrate 200 and material layers for forming the initial memory cells 220′, and etching the material layers and the conductive material by using a line-shaped mask pattern extending in the first direction.

The initial memory cell 220′ may include a stacked structure of an initial bottom electrode 221′, an initial selector pattern 223′, an initial intermediate electrode 225′, an initial phase-change pattern 227′, and an initial top electrode 229′.

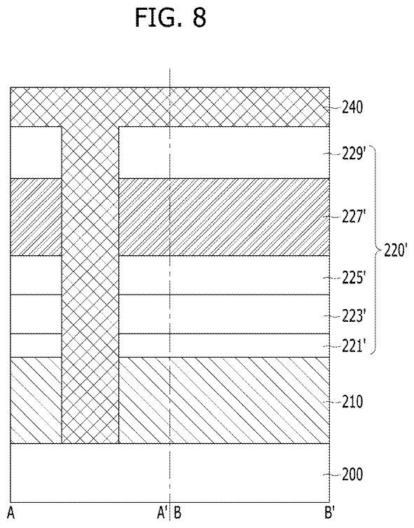

Referring to FIG. 8, a first sealing layer 240 may be formed to fill the space between the lower conductive line 210 and the space between the initial memory cells 220′ over the resultant structure of the process of FIG. 7.

The first sealing layer 240 may be formed of a material with desirable gap-fill characteristics. For example, the first sealing layer 240 may include at least one selected among dielectric silicon-containing materials, such as SiN, SiON, SiCN, SiOC, SiOCN, SiC, SiO, and the like, and dielectric metal oxides, such as hafnium oxide, lanthanum oxide and the like. Also, the first sealing layer 240 may be formed at a relatively low temperature, e.g., at a temperature of approximately 400° C. or lower.

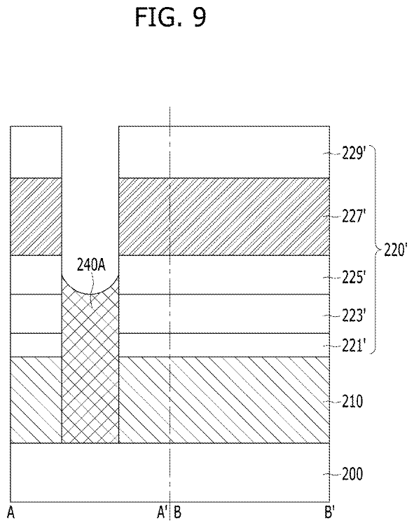

Referring to FIG. 9, a first sealing layer pattern 240A may be formed by removing a portion of the first sealing layer 240 in such a manner that all the sidewalls of the initial phase-change pattern 227′ are exposed.

The upper surface of the first sealing layer pattern 240A may be positioned at a height substantially equal to or lower than the lower surface of the initial phase-change pattern 227′. Also, the height at a point relatively adjacent to the initial memory cells 220′ of the upper surface of the first sealing layer pattern 240A may be higher than the height at a point relatively far from the initial memory cells 220′.

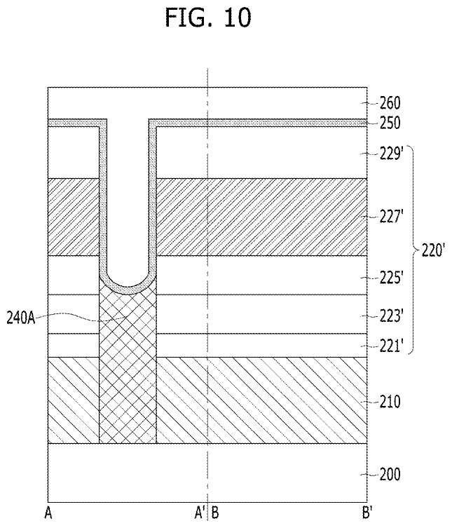

Referring to FIG. 10, a first liner layer 250 and a first dielectric layer 260 may be formed over the resultant structure of the process of FIG. 9.

The first liner layer 250 may be provided to protect the initial phase-change pattern 227′ during the process for forming a subsequent first dielectric layer 260, and the first liner layer 250 may be conformally formed along the profile of the resultant structure of the process of FIG. 9.

The first liner layer 250 may be formed of a material with desirable step coverage characteristics. For example, the first liner layer 250 may include at least one selected among dielectric silicon-containing materials, such as SiN, SiON, SiCN, SiOC, SiOCN, SiC, SiO, and the like, and dielectric metal oxides, such as hafnium oxide, lanthanum oxide and the like. The first liner layer 250 may be formed of a material which is the same as or different from that of the first sealing layer 240. Also, the first liner layer 250 may be formed at a relatively high temperature, e.g., at a temperature of higher than approximately 400° C.

The first dielectric layer 260 may be formed in a thickness that may sufficiently fill the space between the initial memory cells 220′ where the first sealing layer pattern 240A and the first liner layer 250 are formed.

The first dielectric layer 260 may include a dielectric material having a low thermal conductivity. The thermal conductivity of the first dielectric layer 260 may be lower than the thermal conductivity of the first sealing layer pattern 240A and the thermal conductivity of the first liner layer 250. For example, the first dielectric layer 260 may include at least one selected among silicon-containing materials, such as SiN, SiON, SiCN, SiOC, SiOCN, SiC, SiO, and the like, and dielectric metal oxides, such as hafnium oxide and lanthanum oxide and the like. The first dielectric layer 260 may be formed of a material that is different from those of the first sealing layer 240 and the first liner layer 250.

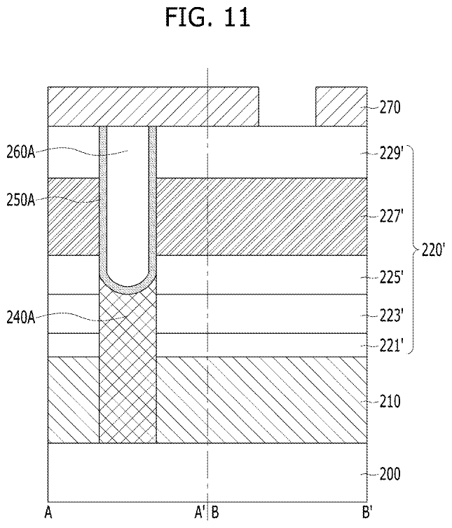

Referring to FIG. 11, a first liner layer pattern 250A and a first dielectric layer pattern 260A may be formed by performing a planarization process until the upper surface of the initial memory cells 220′ is exposed.

Subsequently, an upper conductive line 270 may be formed over the initial memory cells 220′, the first liner layer pattern 250A, and the first dielectric layer pattern 260A. The upper conductive line 270 may be arranged to be spaced apart from each other in the first direction while extending in the second direction. The upper conductive line 270 may be formed by depositing a conductive material for forming the upper conductive line 270 over the initial memory cells 220′, the first liner layer pattern 250A, and the first dielectric layer pattern 260A and etching the conductive material by using a line-shaped mask pattern extending in the second direction.

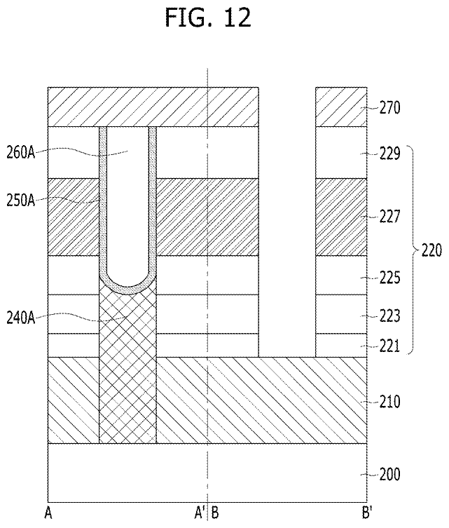

Referring to FIG. 12, memory cells 220 may be formed by etching the initial memory cells 220′ that are exposed by the upper conductive line 270. The etching of the initial memory cells 220′ may be performed with the presence of the mask pattern for forming the upper conductive line 270, which is described above.

As a result of this process, the memory cells 220 each may have a pillar that overlaps with the intersection between the lower conductive line 210 and the upper conductive line 270. In the first direction, both sidewalls of the memory cells 220 may be aligned with both sidewalls of the upper conductive line 270. In the second direction, both sidewalls of the memory cells 220 may be aligned with both sidewalls of the lower conductive line 210. The memory cells 220 may include a stacked structure of the bottom electrode 221, the selector pattern 223, the intermediate electrode 225, the phase-change pattern 227, and the top electrode 229.

Meanwhile, although not illustrated in the drawing, the first sealing layer pattern 240A, the first liner layer pattern 250A, and the first dielectric layer pattern 260A that are exposed by the upper conductive line 270 may also be etched. The etched first sealing layer pattern 240A, the first liner layer pattern 250A, and the first dielectric layer pattern 260A may have a pillar shape while being positioned between the memory cells 220 of a pillar shape that are positioned adjacent to each other in the second direction.

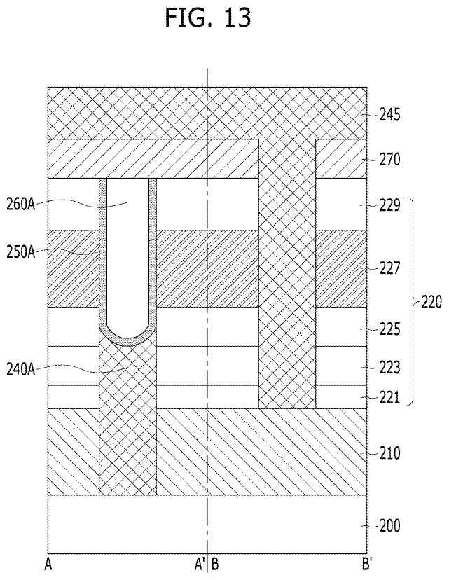

Referring to FIG. 13, a second sealing layer 245 may be formed to fill the space between the upper conductive lines 270 and the space between the memory cells 220 over the resultant structure of the process of FIG. 12. For example, when first and second memory cells 220 neighboring in the first direction are formed, the second sealing layer 245 may be formed to fill a space between the first and second memory cells 220 and a space between the upper conductive lines 270 and over the upper conductive lines 270.

The second sealing layer 245 may be formed of a material with desirable gap-filling characteristics. For example, the second sealing layer 245 may include at least one selected among dielectric silicon-containing materials, such as SiN, SiON, SiCN, SiOC, SiOCN, SiC, SiO, and the like, and dielectric metal oxides, such as hafnium oxide, lanthanum oxide and the like. Also, the second sealing layer 245 may be formed at a relatively low temperature, e.g., at a temperature of approximately 400° C. or lower. The second sealing layer 245 may be formed of the same material as that of the first sealing layer 240.

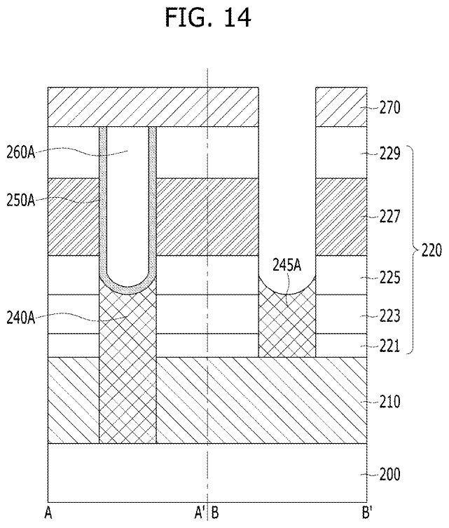

Referring to FIG. 14, a second sealing layer pattern 245A may be formed by removing a portion of the second sealing layer 245 in such a manner that the entire sidewall of the phase-change pattern 227 is exposed. For example, the second sealing layer pattern 245A may be formed by removing a portion of the second sealing layer 245 to expose sidewalls of the phase-change patterns 227 in the first and second memory cells 220 neighboring in the first direction.

The upper surface of the second sealing layer pattern 245A may be positioned at a height substantially equal to or lower than the bottom surface of the phase-change pattern 227. Also, the height at a point that is relatively adjacent to the memory cells 220 of the upper surface of the second sealing layer pattern 245A may be higher than the height at a point relatively far from the memory cells 220.

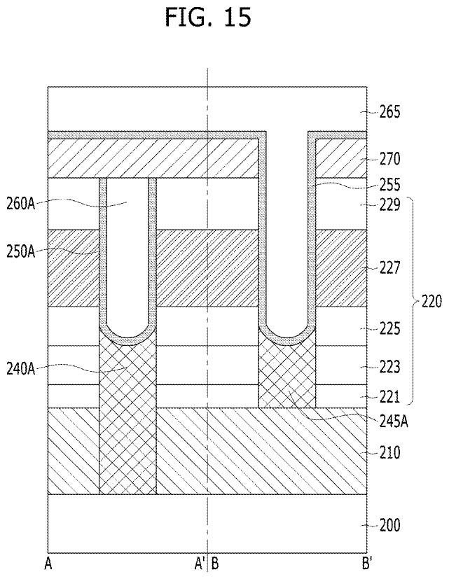

Referring to FIG. 15, a second liner layer 255 and a second dielectric layer 265 may be formed over the resultant structure of the process of FIG. 14. For example, the second liner layer 255 may be formed along sidewalls of the upper conductive lines 270 neighboring in the first direction, portions of the sidewalls of the first and second memory cells 220 exposed by the second sealing layer pattern 245A, and an upper surface of the second sealing layer patter 245A.

The second liner layer 255 may be provided to protect the phase-change pattern 227 during the subsequent process for forming the second dielectric layer 265, and the second liner layer 255 may be conformally formed along the profile of the resultant structure of the process of FIG. 15.

The second liner layer 255 may be formed of a material with desirable step coverage characteristics. For example, the second liner layer 255 may include at least one selected among dielectric silicon- containing materials, such as SiN, SiON, SiCN, SiOC, SiOCN, SiC, SiO, and the like, and dielectric metal oxides, such as hafnium oxide, lanthanum oxide and the like. The second liner layer 255 may be formed of a material which is the same as or different from that of the second sealing layer 245. Also, the second liner layer 255 may be formed at a relatively high temperature, e.g., at a temperature of higher than approximately 400° C. The second liner layer 255 may be formed of the same material as that of the first liner layer 250.

The second dielectric layer 265 may be formed in a thickness that may sufficiently fill the space between the memory cells 220 where the second sealing layer pattern 245A and the second liner layer 255 are formed and the space between the upper conductive lines 270.

The second dielectric layer 265 may include a dielectric material having a low thermal conductivity. The thermal conductivity of the second dielectric layer 265 may be lower than the thermal conductivity of the second sealing layer pattern 245A and the thermal conductivity of the second liner layer 255. For example, the second dielectric layer 265 may include at least one selected among dielectric silicon-containing materials, such as SiN, SiON, SiCN, SiOC, SiOCN, SiC, SiO, and the like, and dielectric metal oxides, such as hafnium oxide, lanthanum oxide and the like. The second dielectric layer 265 may be formed of a material that is different from those of the second sealing layer 245 and the second liner layer 255. Also, the second dielectric layer 265 may be formed of the same material as that of the first dielectric layer 260.

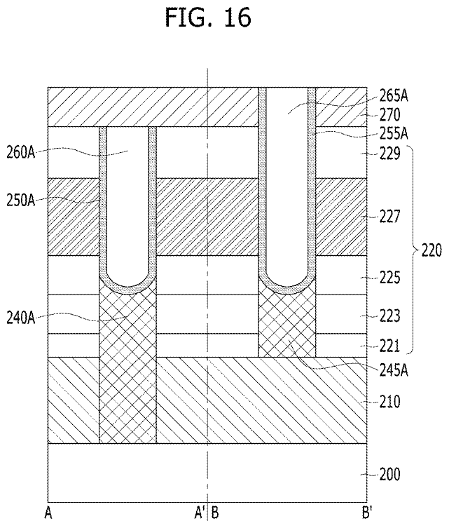

Referring to FIG. 16, a second liner layer pattern 255A and a second dielectric layer pattern 265A may be formed by performing a planarization process until the upper surface of the upper conductive line 270 is exposed.

The semiconductor device in accordance with another embodiment of the present disclosure may be obtained by the fabrication method described above.

Referring to FIG. 16 again, the semiconductor device in accordance with the embodiment of the present disclosure may include the substrate 200, the lower conductive line 210 formed over the substrate 200 and extending in the first direction, the upper conductive line 270 formed over the lower conductive line 210 to be spaced apart from the lower conductive line 210 and extending in the second direction crossing the first direction, and pillar-shaped memory cells 220 each positioned at the intersection between the lower conductive line 210 and the upper conductive line 270. The semiconductor device may further include the first sealing layer pattern 240A, the first liner layer pattern 250A, and the first dielectric layer pattern 260A that fill the space between the lower conductive lines 210 and the space between the memory cells 220 in the second direction. In addition, the semiconductor device may further include the second sealing layer pattern 245A, the second liner layer pattern 255A, and the second dielectric layer pattern 265A that fill the space between the memory cells 220 and the space between the upper conductive lines 270 neighboring in the first direction.

The memory cells 220 each may have a multi-layer structure including the phase-change pattern 227. For example, the memory cells 220 each may include a stacked structure of the bottom electrode 221, the selector pattern 223, the intermediate electrode 225, the phase-change pattern 227, and the top electrode 229.

Here, the first sealing layer pattern 240A may fill at least a portion of the space between the memory cells 220 neighboring in the second direction, and the portion of the space may positioned substantially equal to or lower than the bottom surface of the phase-change pattern 227 while filling the space between the lower conductive lines 210. Furthermore, the upper surface of the first sealing layer pattern 240A may have a sunken shape whose height is high at the edges and low in the center in the second direction. Accordingly, the height at a first point of the upper surface of the first sealing layer pattern 240A positioned at a first distance from the memory cell 220 in the second direction may be higher than the height at a second point of the upper surface of the first sealing layer pattern 240A positioned at a second distance from the memory cell 220, where the second distance is greater than the first distance. For example, the height at the first point of the upper surface of the first sealing layer pattern 240A, that is, the edge, contacting the sidewall of the memory cell 220 may be higher than the height at the second point of the upper surface of the first sealing layer pattern 240A, that is, the center, which is positioned at the same distance from two neighboring memory cells 220 in the second direction.

The first liner layer pattern 250A may be formed over a portion of both sidewalls of the memory cells 220 that is not covered by the first sealing layer pattern 240A in the second direction, and along the profile of the upper surface of the first sealing layer pattern 240A.

The first dielectric layer pattern 260A may fill the remaining portion of the space between the memory cells 220 in the second direction, except for the portion where the first sealing layer pattern 240A and the first liner layer pattern 250A are formed. Specifically, the first dielectric layer pattern 260A may fill the remaining portion of the space between the memory cells 220 neighboring in the second direction, where the remaining portion is unfilled by the first sealing layer pattern 240A and the first liner layer pattern 250A.

The second sealing layer pattern 245A may fill at least a portion of the space between the memory cells 220 neighboring in the first direction, and the portion of the space may be positioned below the bottom surface of the phase-change pattern 227. Furthermore, the upper surface of the second sealing layer pattern 245A may have a sunken shape whose height is high at the edges and low in the center. Accordingly, the height at the first point of the upper surface of the second sealing layer pattern 245A positioned at the first distance from the memory cell 220 in the first direction may be greater than the height at the second point of the upper surface of the second sealing layer pattern 245A positioned at the second distance from the memory cell 220, where the second distance is greater than the first distance. For example, the height at the first point of the upper surface of the second sealing layer pattern 245A, that is, the edge, contacting the sidewall of the memory cell 220 may be greater than the height at the second point of the upper surface of the second sealing layer pattern 245A, that is, the center, which is positioned at the same distance from two neighboring memory cells 220 in the first direction.

The second liner layer pattern 255A may be formed along the profile of both sidewalls of the upper conductive line 270, which is a portion that is not covered by the second sealing layer pattern 245A of both sidewalls of the memory cells 220 in the first direction, and the upper surface of the second sealing layer pattern 245A.

The second dielectric layer pattern 265A may be formed to fill the remaining portion of the space between the upper conductive lines 270 and the space between the memory cells 220 in the first direction, except for a portion where the second sealing layer pattern 245A and the second liner layer pattern 255A are formed. Specifically, the second dielectric layer pattern 265A may fill the remaining portion of the space between the memory cells 220 neighboring in the first direction, where the remaining portion is unfilled by the second sealing layer pattern 245A and the second liner layer pattern 255A.

Meanwhile, in the above embodiments of the present disclosure, a case where the memory cells include a phase-change pattern as a data storage element, the concept and spirit of the present disclosure are not limited thereto, and another memory pattern generating heat may be used instead of the phase-change pattern. In the case of a memory pattern that generates heat during an operation, the heat may be lost or delivered to a neighboring memory pattern to deteriorate the operation characteristics of the memory cells. Even in this case, the above-described effects may be obtained by filling the space between the memory pattern positioned below the memory pattern with a sealing layer pattern, and forming a liner layer pattern and a dielectric layer pattern between the memory patterns. The memory pattern may include a variable resistive material that stores different data by switching between different resistance states, or a material that stores different data in different ways.

According to the embodiment of the present disclosure, provided are a semiconductor device that may improve the operation characteristics of memory cells and reduce the process difficulty, and a method for fabricating the semiconductor device.

While the present disclosure has been described with respect to the specific embodiments, it will be apparent to those skilled in the art that diverse changes and modifications may be made without departing from the spirit and scope of the invention as defined in the following claims.

What is claimed is:

1. A semiconductor device, comprising:
a substrate;
a plurality of memory cells positioned over the substrate, each of the plurality of memory cells having a multi-layer structure including a memory pattern;
a sealing layer pattern filling a lower portion of a space between the memory cells, the lower portion being positioned below a bottom surface of the memory pattern;
a liner layer pattern formed along a surface of an upper portion of the space to partially fill the upper portion; and
a dielectric layer pattern filling a remaining portion of the space unfilled by the sealing layer pattern and the liner layer pattern.

2. The semiconductor device of claim 1, wherein a height of an upper surface of the sealing layer pattern at a first distance from the memory cell is greater than a height of the upper surface of the sealing layer pattern at a second distance from the memory cell, the second distance being greater than the first distance.

3. The semiconductor device of claim 1, wherein a thermal conductivity of the dielectric layer pattern is lower than a thermal conductivity of the liner layer pattern and a thermal conductivity of the sealing layer pattern.

4. The semiconductor device of claim 1, wherein the liner layer pattern covers a sidewall of the memory pattern.

5. The semiconductor device of claim 1, wherein the memory cell further includes a selector pattern positioned below the memory pattern, and wherein the sealing layer pattern covers a sidewall of the selector pattern.

6. The semiconductor device of claim 1, further comprising:
a plurality of lower conductive lines extending in a first direction; and
a plurality of upper conductive lines extending in a second direction crossing the first direction,
wherein the memory cells overlap with intersections between the lower conductive lines and the upper conductive lines.

7. The semiconductor device of claim 6, wherein the sealing layer pattern includes a first sealing layer pattern positioned between the memory cells neighboring in the second direction, and a second sealing layer pattern positioned between the memory cells neighboring in the first direction, and
wherein the first sealing layer pattern further fills a space between the lower conductive lines.

8. The semiconductor device of claim 6, wherein the liner layer pattern includes a first liner layer pattern positioned between the memory cells neighboring in the second direction, and a second liner layer pattern positioned between the memory cells neighboring in the first direction, and
wherein the second liner layer pattern is further formed on sidewalls of the upper conductive lines.

9. The semiconductor device of claim 6, wherein the dielectric layer pattern includes a first dielectric layer pattern positioned between the memory cells neighboring in the second direction, and a second dielectric layer pattern positioned between the memory cells neighboring in the first direction, and
wherein the second dielectric layer pattern is further positioned between the upper conductive lines.

10. The semiconductor device of claim 1, wherein the memory pattern includes a phase-change pattern.

11. A method for fabricating a semiconductor device, comprising:
forming a plurality of memory cells, each of the plurality of memory cells having a multi-layer structure including a memory pattern over a substrate;
forming a sealing layer of a thickness that fills a space between the memory cells;
forming a sealing layer pattern by removing a portion of the sealing layer to expose a sidewall of the memory pattern;
forming a liner layer along a portion of a sidewall of the memory cell exposed by the sealing layer pattern and an upper surface of the sealing layer pattern; and
forming a dielectric layer over the liner layer.

12. The method of claim 11, further comprising:
after the forming of the dielectric layer, performing a planarization process to expose an upper surface of the memory cell.

13. The method of claim 11, wherein the forming of the sealing layer is performed at a lower temperature than that of the forming of the liner layer.

14. The method of claim 11, wherein a thermal conductivity of the dielectric layer is lower than a thermal conductivity of the liner layer and a thermal conductivity of the sealing layer.

15. The method of claim 11, wherein the memory cell further includes a selector pattern positioned below the memory pattern, and wherein the sealing layer pattern covers a sidewall of the selector pattern.

16. The method of claim 11, wherein the memory pattern includes a phase-change pattern.

17. A method for fabricating a semiconductor device, comprising:
forming stacked structures, each of the stacked structures including a lower conductive line and an initial memory cell, the initial memory cell having a multi-layer structure including an initial memory pattern, the initial memory cell extending in a first direction over a substrate;
forming a first sealing layer filling a space between the stacked structures;
forming a first sealing layer pattern by removing a portion of the first sealing layer to expose a sidewall of the initial memory pattern;
forming a first liner layer over a portion of a sidewall of the initial memory cell exposed by the first sealing layer pattern and an upper surface of the first sealing layer pattern;
forming a first dielectric layer over the first liner layer;
forming a first liner layer pattern and a first dielectric layer pattern by performing a planarization process to expose an upper surface of the initial memory cell;
forming a plurality of upper conductive lines extending in a second direction crossing the first direction over the initial memory cell, the first liner layer pattern, and the first dielectric layer pattern; and
forming a plurality of memory cells by etching the initial memory cell exposed by the upper conductive lines, each of the plurality of memory cells including a memory pattern.

18. The method of claim 17, wherein the forming of the first sealing layer is performed at a lower temperature than the forming of the first liner layer.

19. The method of claim 17, wherein a thermal conductivity of the first dielectric layer is lower than a thermal conductivity of the first liner layer and a thermal conductivity of the first sealing layer.

20. The method of claim 17, wherein the initial memory cell further includes an initial selector pattern positioned below the initial memory pattern, and
wherein the first sealing layer pattern covers a sidewall of the initial selector pattern.

21. The method of claim 17, wherein the plurality of memory cells includes a first memory cell and a second memory cell neighboring in the first direction, the first memory cell including a first memory pattern and the second memory cell including a second memory pattern, the method further comprising:
after the forming of the memory cells, forming a second sealing layer filling a space between the first memory cell and the second memory cell;
forming a second sealing layer pattern by removing a portion of the second sealing layer to expose sidewalls of the first and second memory patterns;
forming a second liner layer along sidewalls of the upper conductive lines neighboring in the first direction, portions of sidewalls of the first and second memory cells exposed by the second sealing layer pattern, and an upper surface of the second sealing layer pattern;
forming a second dielectric layer over the second liner layer; and
forming a second liner layer pattern and a second dielectric layer pattern by performing a planarization process to expose upper surfaces of the upper conductive lines.

22. The method of claim 21, wherein the forming of the second sealing layer is performed at a lower temperature than the forming of the second liner layer.

23. The method of claim 21, wherein a thermal conductivity of the second dielectric layer is lower than a thermal conductivity of the second liner layer and a thermal conductivity of the second sealing layer.

24. The method of claim 21, wherein each of the first and second memory cells further includes a selector pattern positioned below the first and second memory patterns, and wherein the second sealing layer pattern covers a sidewall of the selector pattern.

25. The method of claim 17, wherein the memory pattern includes a phase-change pattern.
